(19) United States
(12) Patent Application Publication
(10) Pub. No.: US 2014/0226345 A1
(43) Pub. Date: Aug. 14, 2014

(54) LIGHT-EMITTING DEVICE PACKAGES

(71) Applicant: SAMSUNG ELECTRONICS CO., LTD., Suwon-si (KR)

(72) Inventors: Jong-sup SONG, Suwon-si (KR); Sung-soo PARK, Suwon-si (KR)

(73) Assignee: SAMSUNG ELECTRONICS CO., LTD., Suwon-si (KR)

(21) Appl. No.: 14/032,055

(22) Filed: Sep. 19, 2013

(30) Foreign Application Priority Data
Feb. 14, 2013 (KR) 10-2013-0016055

(51) Int. Cl. H01L 33/48; F21V 23/06

(52) U.S. Cl. CPC H01L 33/483; F21V 23/06
USPC 362/382; 257/99; 257/98

(57) ABSTRACT

The present application describes a light-emitting device package including a package substrate having first and second conductive layers that are spaced apart from each other. A light-emitting device is mounted on the package substrate to overlap with the first and second conductive layers. A portion of the first conductive layer that does not overlap with the light-emitting device includes a slit.

### CROSS-REFERENCE TO RELATED APPLICATIONS

This application claims priority under 35 U.S.C. §119 from Korean Patent Application No. 10-2013-0016055, filed on Feb. 14, 2013, in the Korean Intellectual Property Office, the disclosure of which is incorporated herein in its entirety by reference.

### TECHNICAL FIELD

The inventive concept relates to a light-emitting device package, and more particularly, to a flip-chip light-emitting device package.

### BACKGROUND

Light-emitting diodes (LEDs) are semiconductor devices that include a compound semiconductor material. LEDs are mainly used in light-emitting device packages in which a light-emitting device is mounted on a package substrate. The package substrate mainly includes a ceramic substrate, and a metal electrode is formed between the package substrate and the light-emitting device. Due to a difference between the thermal expansion coefficients of the package substrate and the light-emitting device or a difference between the thermal expansion coefficients of the metal electrode and the light-emitting device, a thermal stress may be applied to the light-emitting device package. Accordingly, the light-emitting device can become damaged by the thermal stress, and thus, the light-emitting device package may have poor reliability.

### SUMMARY

The inventive concept provides a light-emitting device package having improved reliability.

According to an aspect of the inventive concept, there is provided a light-emitting device package. The package includes a package substrate light-emitting first and second conductive layers that are spaced apart from each other. A light-emitting device is mounted on the package substrate to overlap with the first and second conductive layers. A portion of the first conductive layer that does not overlap with the light-emitting device has a first slit.

A longitudinal direction of the first slit may be substantially parallel with a side of the light-emitting device.

A length of the first slit may be longer than or equal to a length of a side of the light-emitting device.

The first conductive layer may include a first region that overlaps with the light-emitting device, the second conductive layer may include a second region that overlaps with the light-emitting device, and an electrode separating region between the first and second regions may extend in a direction that is substantially parallel with a side of the light-emitting device.

A portion of the second conductive layer that does not overlap with the light-emitting device has a second slit.

An area of the first region may be wider than an area of the second region, and a width of the first slit is wider than a width of the second slit.

A portion of the first conductive layer that overlaps with the light-emitting device has a third slit, and the third slit may be substantially parallel with the first slit.

The light-emitting device package may further include a guide layer on an upper surface of the package substrate. The guide layer may be at a predetermined distance from outer sides of the first and second conductive layers and has an annular shape.

The guide layer and the first and second conductive layers may be formed of the same material.

The light-emitting device package may further include a reflective layer which encloses sides of the light-emitting device on the package substrate and extends to a part of an inner sidewall of the guide layer.

According to another aspect of the inventive concept, there is provided a light-emitting device package. The package includes first and second conductive layers on a substrate. The first and second layers are spaced apart from each other and adjacent to both sides of an electrode separating region that extends in a predetermined direction. A light-emitting device is mounted on the first and second conductive layers. The light-emitting device overlaps with the electrode separating region. The first conductive layer includes a first slit extending in an extension direction of the electrode separating region. The second conductive layer includes a second slit extending in the extension direction of the electrode separating region.

A side of the light-emitting device may be substantially parallel with the extension direction of the electrode separating region.

The light-emitting device may have a symmetric structure in a direction perpendicular to the extension direction of the electrode separating region.

The first conductive layer may have a symmetrical structure in a direction perpendicular to the extension direction of the electrode separating region, and the second conductive layer may have a symmetric structure in a direction perpendicular to the extension direction of the electrode separating region.

The first slit may have a symmetrical structure in a direction perpendicular to the extension direction of the electrode separating region, the second slit may have a symmetric structure in a direction perpendicular to the extension direction of the electrode separating region.

According to yet another aspect of the inventive concept, there is provided a light-emitting device system. The system includes a power supply device for supplying power. A light-emitting device package is configured to receive the power from the power supply device. The package includes a package substrate having first and second conductive layers that are spaced apart from each other. A light-emitting device is mounted on the package substrate to overlap with the first and second conductive layers. A first slit is provided in a portion of the first conductive layer that does not overlap with the light-emitting device.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

Exemplary embodiments of the inventive concept will be more clearly understood from the following detailed description taken in conjunction with the accompanying drawings in which:

FIG. 1A is a plan view illustrating a light-emitting device package according to an exemplary embodiment of the inventive concept;

FIG. 1B is a cross-sectional view taken along line B-B′ of FIG. 1A;

FIG. 2A is a plan view illustrating a light-emitting device package according to another exemplary embodiment of the inventive concept;

FIG. 2B is a cross-sectional view taken along line B-B′ of FIG. 2A;

FIG. 3A is a plan view illustrating a light-emitting device package according to another exemplary embodiment of the inventive concept;

FIG. 3B is a cross-sectional view taken along line B-B′ of FIG. 3A;

FIG. 4A is a plan view illustrating a light-emitting device package according to another exemplary embodiment of the inventive concept;

FIG. 4B is a cross-sectional view taken along line B-B′ of FIG. 4A;

FIG. 5A is a plan view illustrating a light-emitting device package according to another exemplary embodiment of the inventive concept;

FIG. 5B is a cross-sectional view taken along line B-B′ of FIG. 5A;

FIG. 6 is a cross-sectional view illustrating a light-emitting device package according to another exemplary embodiment of the inventive concept; and

FIG. 7 is a block diagram illustrating a light-emitting device system including a light-emitting device package according to another exemplary embodiment of the inventive concept.

### DETAILED DESCRIPTION

In the following detailed description, numerous specific details are set forth by way of embodiments in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

The inventive concept will now be described more fully with reference to the accompanying drawings, in which exemplary embodiments of the inventive concept are shown. The inventive concept may, however, be embodied in many different forms and should not be construed as being limited to the embodiments set forth herein; rather, these embodiments are provided so that this disclosure will be thorough and complete, and will fully convey the inventive concept to those skilled in the art. In the drawings, the thicknesses of layers and regions are exaggerated for clarity.

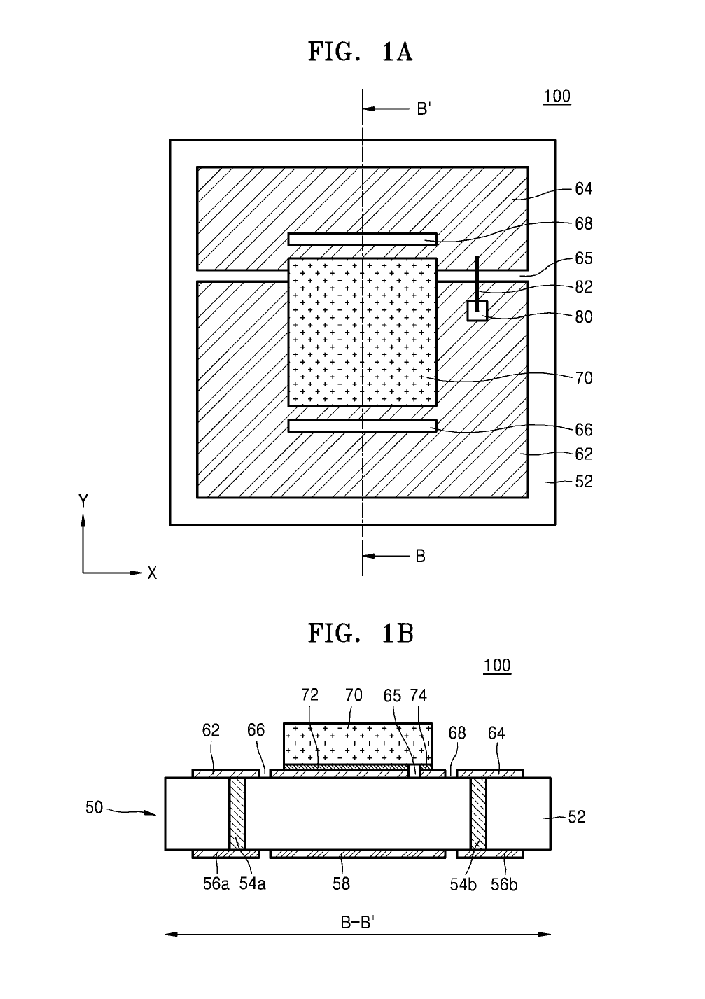

FIG. 1A is a plan view illustrating a light-emitting device package 100 according to an exemplary embodiment of the inventive concept. FIG. 1B is a cross-sectional view taken along line B-B′ of FIG. 1A.

Referring to FIGS. 1A and 1B, the light-emitting device package 100 includes a package substrate 50 and a light-emitting device 70 mounted on the package substrate 50.

The package substrate 50 includes a substrate 52, a first conductive layer 62, a second conductive layer 64, through-substrate vias 54a and 54b, and wirings 56a and 56b.

The substrate 52 may be an insulating substrate such as an aluminum oxide (Al₂O₃) substrate, an aluminum nitride (AlN) substrate, a silicon nitride (SiN) substrate, or a silicon oxide (SiO₂) substrate, or a semiconductor substrate such as a silicon (Si) substrate. First and second wirings 56a and 56b may penetrate the substrate 52. Also, first and second wirings 56a and 56b may be formed on a lower surface of the substrate 52 and may be respectively connected to the first and second through-substrate vias 54a and 54b. A heat dissipation layer 58 may be formed on the lower surface of the substrate 52 to be spaced apart from the first and second wirings 56a and 56b and may include the same material as the first and second wirings 56a and 56b. The heat dissipation layer 58 may release heat generated by the light-emitting device 70 to the outside the package substrate 50. Although not shown in FIGS. 1A and 1B, a heat sink (not shown) may be formed on the lower surface of the package substrate 50.

The first and second conductive layers 62 and 64 may be formed on an upper surface of the substrate 52 to be spaced apart from each other. An electrode separating region 65 may be defined by a space between the first and second conductive layers 62 and 64. The electrode separating region 65 may extend in one direction on the substrate 52. For example, in FIG. 1A, the electrode separating region 65 extends in an x direction, and the first and second conductive layers 62 and 64 are disposed along both sides of the electrode separating region 65. The electrode separating region 65 may be spaced from a center of the substrate 50, and may extend along a direction substantially parallel with a side of the substrate 52. An area of the first conductive layer 62 may be different from an area of the second conductive layer 64. For example, in FIG. 1A, a distance in a y direction between the electrode separating region 65 and a center of the substrate 52 is constant, and the area of the first conductive layer 62 is greater than the area of the second conductive layer 64.

Each of the first conductive layer 62, the second conductive layer 64, and the electrode separating region 65 may have a symmetrical structure with respect to the y direction. In this case, although a temperature of the light-emitting device package 100 rises, a stress applied to the light-emitting device 70 due to thermal expansion of the first and second conductive layers 62 and 64 may be uniformly dispersed.

A first slit 66 may be formed in a portion of the first conductive layer 62 that does not overlap with the light-emitting device 70. The first slit 66 may be an opening of which length is greater than a width thereof, and a portion of the upper surface 52 may be exposed by the first slit 66. In exemplary embodiments, the length of the first slit 66 may be parallel with an extension direction of the electrode separating region 65. The length of the first slit 66 may be longer than or equal to a length of a side of the light-emitting device 70. The first slit 66 may be adjacent to a side of the light-emitting device 70. The first slit 66 may serve as a stress release region that offsets volume changes caused by the thermal expansion of the first conductive layer 62 due to heat generated in an operation of the light-emitting device 70 or in a high temperature process of bonding the light-emitting device 70.

A second slit 68 may be formed in a portion of the second conductive layer 64 that does not overlap with the light-emitting device 70. The second slit 68 may be formed so that a length thereof in a longitudinal direction is substantially parallel with the extension direction of the electrode separating region 65 and may have the same length as the first slit 66.

In exemplary embodiments, the first and second conductive layers 62 and 64 may be formed of copper (Cu), aluminum (Al), nickel (Ni), titanium (Ti), tungsten (W), silver (Ag), gold (Au), or the like as a single layer or a dual layer. Each of the first and second conductive layers 62 and 64 may be formed to a thickness between several micrometers (μm) and hundreds of μm. For example, each of the first and second conductive layers 62 and 64 may be formed to a thickness between 50 μm and 100 μm, but the thickness of each of the first and second conductive layers 62 and 64 is not limited thereto.

A reflective layer (not shown) including a metal having a high reflectivity may further formed on the first and second conductive layers 62 and 64. For example, if the first and second conductive layers 62 and 64 include Cu, the reflective layer including Ag may be formed to a predetermined thicknesses on the first and second conductive layers 62 and 64. Therefore, light emitted from the light-emitting device 70 downwards may be reflected in an upward direction.

The light-emitting device 70 may be mounted on the package substrate to overlap with the first and second conductive layers 62 and 64. The light-emitting device 70 may be disposed at a center of the package substrate 50, and n- and p-type electrodes (not shown) formed on a lower surface of the light-emitting device 70 may be respectively connected to the first and second conductive layer 62 and 64. The first and second conductive layers 62 and 64 are electrically connected to the first and second wirings 56a and 56b formed on the lower surface of the substrate 52 through the first and second through-substrate vias 54a and 54b. In other words, the light-emitting device 70 may be mounted via a flip-chip method.

In exemplary embodiments, the light emitting device 70 may be a blue light-emitting diode (LED) chip, a green LED chip, a red LED chip, a yellow LED chip, or an UV LED chip, but other chip types of the light-emitting device 70 can be used.

First and second bonding parts 72 and 74 are formed on a lower surface of the light-emitting device 70 and are respectively bonded onto the first and second conductive layers 62 and 64. In exemplary embodiments, the first and second bonding parts 72 and 74 may include an eutectic bonding material and may be formed to a thickness of several μm. The eutectic bonding material may include a material such as Au—Sn, Au—Ni, Au—Ge, Al—Ge, Au—In, Ag—Sn, In—Sn, Ag—Sn—Cu, or the like.

If the light-emitting device 70 is mounted by way of a solder bump, a position of the light-emitting device 70 may be moved due to mobility of the solder bump melted in a reflow process. Therefore, an arrangement precision of the light-emitting device 70 may be lowered. To solve this problem, a sufficient gap between the n and p electrodes of the light-emitting device 70 is required, and thus, an area of the n electrode may be reduced. As the area of the n electrode is reduced, an effective region for emitting light is reduced, thereby lowering the light efficiency of the light-emitting device 70. According to the inventive concept, if the light-emitting device 70 is mounted by using the eutectic bonding material, bonding strengths of the first and second bonding parts 72 and 74 may be high, and reliable bonding between the light-emitting device 70 and the substrate 52 may be realized. The area of the n electrode may be increased due to the high arrangement precision, thereby improving the light efficiency of the light-emitting device 70.

In exemplary embodiments, the light-emitting device 70 may be disposed so that a side of the light-emitting device 70 is parallel with the extension direction (the x direction of FIG. 1A) of the electrode separating region 65. When a first region (not shown) is defined by a portion of the first conductive layer 62 overlapping with the light-emitting device 70, and a second region (not shown) is defined by a portion of the second conductive layer 64 overlapping the light-emitting device 70, the first and second regions may be spaced apart from each other, and may be adjacent to both sides of the electrode separating region 65. In FIG. 1A, an area of the first region may be greater than an area of the second region. In exemplary embodiments, the first region may be electrically connected to the n electrode of the light-emitting device 70, and the second region may be electrically connected to the p electrode of the light-emitting device 70.

As described above, the first and second conductive layers 62 and 64, the light-emitting device 70, and the substrate 52 may thermally expand due to heat generated by the light-emitting device in an operation of the light-emitting device package 100 or in a high temperature process of bonding the light-emitting device 70. In general, the thermal expansion coefficients of the first and second conductive layers 62 and 64 including the conductive material may be higher than a thermal expansion coefficient of the substrate 52 including a ceramic material or a thermal expansion coefficient of the light-emitting device 70 including a compound semiconductor material such as gallium nitride. Therefore, in a conventional light-emitting device package, when a stress is applied to a light-emitting device due to the difference between thermal expansion coefficients of first and second conductive layers, the stress is concentrated on a region between the n and p electrodes of the light-emitting device. Therefore, cracks may occur in the light-emitting device.

According to the inventive concept, each of the first and second conductive layers 62 and 64 are symmetrical in a direction perpendicular to the extension direction of the electrode separating region 65. Also, the light-emitting device 70 is symmetrical with respect to the extension direction of the electrode separating region 65. Therefore, the stress applied to the light-emitting device 70 due to the thermal expansions of the first and second conductive layers 62 and 64 may be uniformly dispersed. The first and second slits 66 and 68 respectively formed in the first and second conductive layers 62 and 64 are disposed to be parallel with a side of the light-emitting device 70 and to be symmetrical in the direction perpendicular to the extension direction of the electrode separating region 65. Therefore, the first and second slits 66 and 69 may serve as stress releasing parts that offset the thermal expansions of the first and second conductive layers 62 and 64, thereby reducing the stress applied to the light-emitting device 70.

The light-emitting device package 100 may further include a zener diode 80 that is mounted on the first conductive layer 62. The zener diode 80 may protect the light-emitting device 70 from static electricity that may be generated in the light-emitting device package 100 or from abnormal changes in a voltage supplied to the light-emitting device 70. One of positive and negative electrodes of the zener diode 80 may be electrically connected to the first conductive layer 62, and the other electrode of the zener diode 80 may be electrically connected to the second conductive layer 64 through a wire 82. Therefore, the zener diode 80 may be connected to the light-emitting device 70 in parallel.

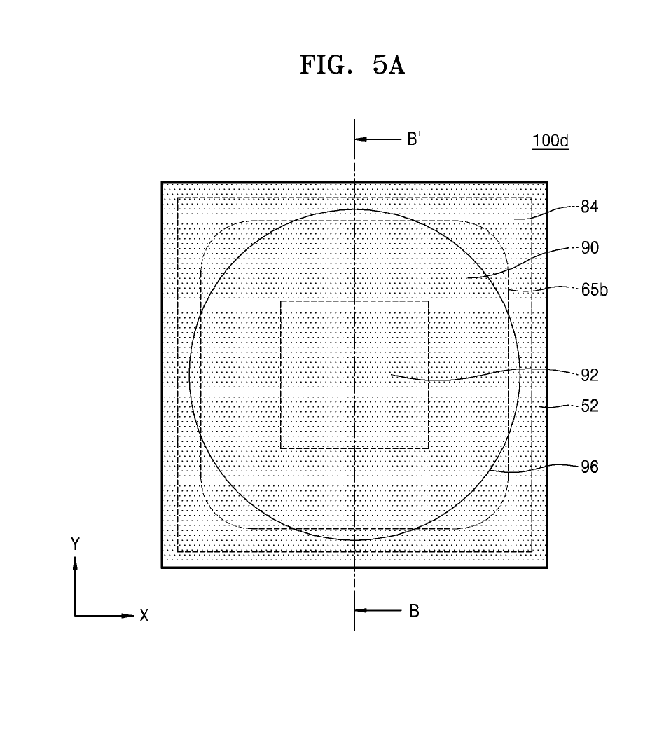

Although not shown in FIGS. 1A and 1B, the light-emitting device package 100 may further include a fluorescent layer 92 of FIG. 5B that covers an upper surface of the light-emitting device 70 and a lens 96 of FIG. 5B that is formed on the fluorescent layer 92.

A method of manufacturing the light-emitting device package 100 shown in FIGS. 1A and 1B will now be described.

The through-substrate vias 54a and 54b and the wirings 56a and 56b may be formed on the substrate 52. For example, a process of forming the through-substrate vias 54a and 54b may be performed by using an etching process of forming through-substrate holes (not shown) and a plating process of filling the through-substrate holes with a conductive material, etc. However, processes of forming the through-substrate vias 54a and 54b and the wirings 56a and 56b are not limited thereto.

The first and second conductive layers 62 and 64 may be formed on the substrate 52. In an exemplary process of forming the first and second conductive layers 62 and 64, a conductive layer (not shown) may be formed on the substrate 52 and then patterned to form the first and second conductive layers 62 and 64 that are spaced apart from each other with a predetermined gap. The first and second slits 66 and 68 may also be patterned in the process of patterning the conductive layer.

In another exemplary process of forming the first and second conductive layers 62 and 64, a seed layer (not shown) may be formed on the substrate 52 by using a sputtering method or the like and then patterned to form first and second seed patterns (not shown) that are spaced apart from each other with a predetermined gap. Parts in which the first and second slits 66 and 68 are respectively formed may also be patterned in the process of patterning the seed layer. In other words, the seed layer may not be formed in a part of the first seed pattern where the first slit 66 is to be formed and a part of the second seed pattern where the second slit 68 is to be formed. A conductive material may be grown to a predetermined thickness on the first and second seed patterns by using an electroplating method, an electroless plating, or the like to respectively form the first and second conductive layers 62 and 64.

The light-emitting device 70 may be mounted on the substrate 52 on which the first and second conductive layers 62 and 64 have been formed by using an eutectic bonding method. For example, an eutectic bonding material (not shown) may be bonded onto a lower surface of the light-emitting device 70, and the light-emitting device 70 may be disposed to overlap with the first and second conductive layers 62 and 64, and then a temperature of the substrate 52 may be raised to an eutectic bonding temperature (i.e., a melting temperature of the eutectic bonding material). Therefore, the first and second bonding parts 72 and 74 are formed on the lower surface of the light-emitting device 70 to be respectively bonded to the first and second conductive layers 62 and 64. As described above, if the eutectic bonding method is used, the arrangement precision is improved more than in the case where a conventional solder bump is used.

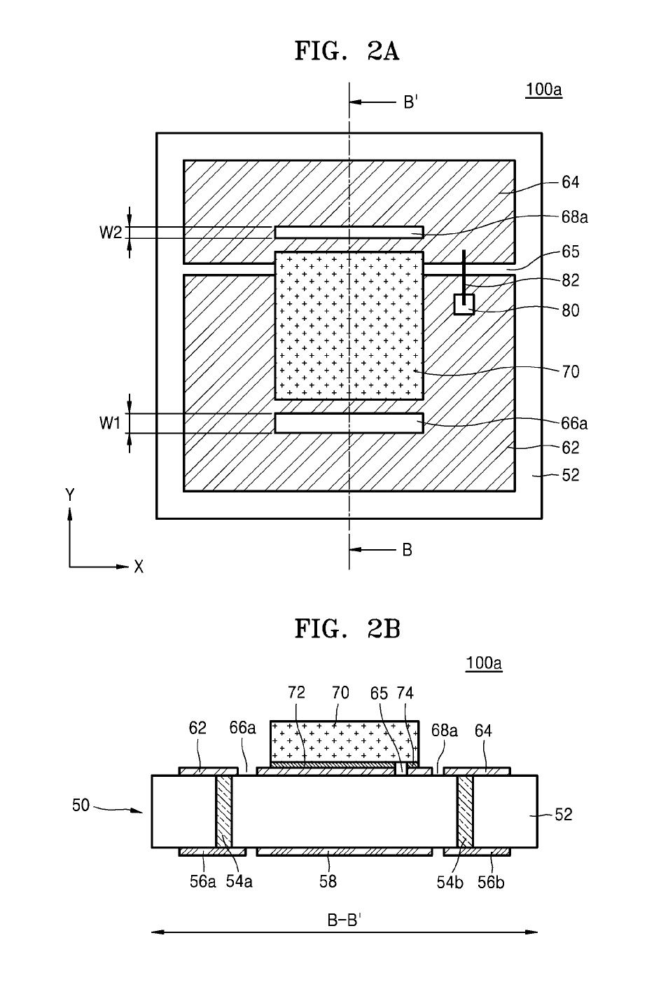

FIG. 2A is a plan view illustrating a light-emitting device package 100a according to an exemplary embodiment of the inventive concept. FIG. 2B is a cross-sectional view of the light-emitting device package 100a taken along line B-B′ of FIG. 2A. The light-emitting device package 10a is similar to the light-emitting device package 100 described with reference to FIGS. 1A and 1B except shapes of first and second slits 66a and 68a.

Referring to FIGS. 2A and 2B, first and second conductive layers 62 and 64 respectively include first and second slits 66a and 68a that are substantially parallel with an extension direction of an electrode separating region 65. The first and second slits 66a and 68a may have the same lengths as a side of a light-emitting device 70, but the lengths of the first and second slits 66a and 68a are not limited thereto.

In exemplary embodiments, the first slit 66a may have a first width W1 and the second slit 68a may have a second width W2, and the first width W1 may be greater than the second width W2. As described above, to improve the light extraction efficiency of the light-emitting device 70, an area of an n electrode (not shown) of the light-emitting device 70 may be greater than an area of a p electrode (not shown) thereof. Since, the first conductive layer 62 is connected to the n electrode of the light-emitting device 70 and the second conductive layer 64 is connected to the p electrode thereof, an area of the first conductive layer 62 may be greater than an area of the second conductive layer 64. Therefore, a volume of the first conductive layer 62 expanding due to a rise in a temperature of the light-emitting device package 100a may be greater than an expanding volume of the second conductive layer 64. Therefore, a first width W1 of the first slit 66a formed in the first conductive layer 62 may be greater than a second width W2 formed in the second slit 68a, so that the first slit 66a may operate as a stress release part that effectively relieves a thermal expansion of the first conductive layer 62.

For example, a ratio between the first width W1 of the first slit 66a and the second width W2 of the second slit 68a may be designed to be equal to a ratio between the areas of the first and second conductive layers 62 and 64. However, the ratio of the first and second widths W1 and W2 is not limited thereto.

FIG. 2A illustrates the light-emitting device package 100a in which a length of the first slit 66a is equal to a length of the second slit 68a. However, the length of the first slit 66a may be longer than the length of the second slit 68a.

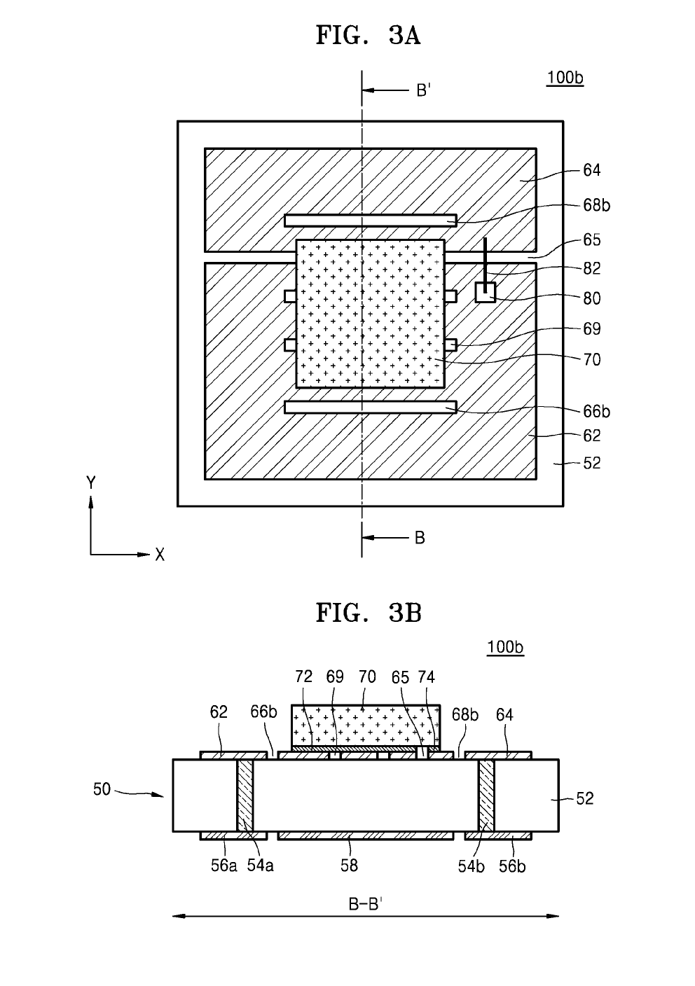

FIG. 3A is a plan view illustrating a light-emitting device package 100b according to an exemplary embodiment of the inventive concept. FIG. 3B is a cross-sectional view of the light-emitting device package 100b taken along line B-B′ of FIG. 3A.

The light-emitting device package 100b is similar to the light-emitting device package 100 described with reference to FIGS. 1A and 1B except that the first conductive layer 62 further includes third slits 69. Thus, only different contents with respect to the light-emitting device package 100b will be described below.

Referring to FIGS. 3A and 3B, first and second conductive layers 62 and 64 respectively include first and second slits 66b and 68b that are respectively formed in parts of the first and second conductive layers 62 and 64 that do not overlap with a light-emitting device 70. The first and second slits 66b and 68b may be formed to be parallel with a side of the light-emitting device 70.

The first conductive layer 62 may further include the third slit(s) 69 that are formed in a part of the first conductive layer 62 overlapping with the light-emitting device 70. The third slit(s) 69 may be formed to be substantially parallel with an extension direction of an electrode separating region 65 and the first slit 66b.

In exemplary embodiments, the third slit(s) 69 may have the same width and length as the first slit 66b, but the length of the third slit(s) 69 is not limited thereto. For example, although the length of the third slit(s) 69 is different from the length of the first slit 66b, the third slit(s) 69 may be symmetrical in a direction perpendicular to the extension direction of the electrode separating region 65.

The length of the third slit(s) 69 may be equal to or greater than a length of a side of the light-emitting device 70. For example, if the length of the third slit(s) 69 is greater than a first width of the light-emitting device 70 in an x direction, the third slit(s) 69 and the light-emitting device 70 may overlap with each other in the x direction. Therefore, a stress caused by a thermal expansion of the first conductive layer 62 in a y direction may be offset too.

Two third slits 69 are formed at a predetermined gap from each other in FIG. 3A, but the number of third slits 69 is not limited thereto. In exemplary embodiments, a plurality of third slits 69 having the same width may be formed at the same distance from one another in the y direction. In this case, stress applied to the light-emitting device 70 due to the thermal expansion of the first conductive layer may be effectively released.

According to the inventive concept, the third slits 69 are formed in a part of the first conductive layer 62 overlapping with the light-emitting device 70. As described above, an area of a part (a first region (not shown)) of the first conductive layer 62 overlapping with the light-emitting device 70 may be greater than an area of a part (a second region (not shown)) of the second conductive layer 64 overlapping with the light-emitting device 70 to improve light extraction efficiency of the light-emitting device 70. In a general light-emitting device package, a stress caused by a thermal expansion of the first region may be remarkably greater than a stress caused by a thermal expansion of the second region. Therefore, a distribution of a stress applied to a light-emitting device may be non-uniform, and thus, cracks or the like may occur in the light-emitting device. If the third slit(s) 69 are formed in a part of the first conductive layer 62 below the light-emitting device 70, a stress applied to the light-emitting device 70 due to the thermal expansion of the first conductive layer 62 may be remarkably released.

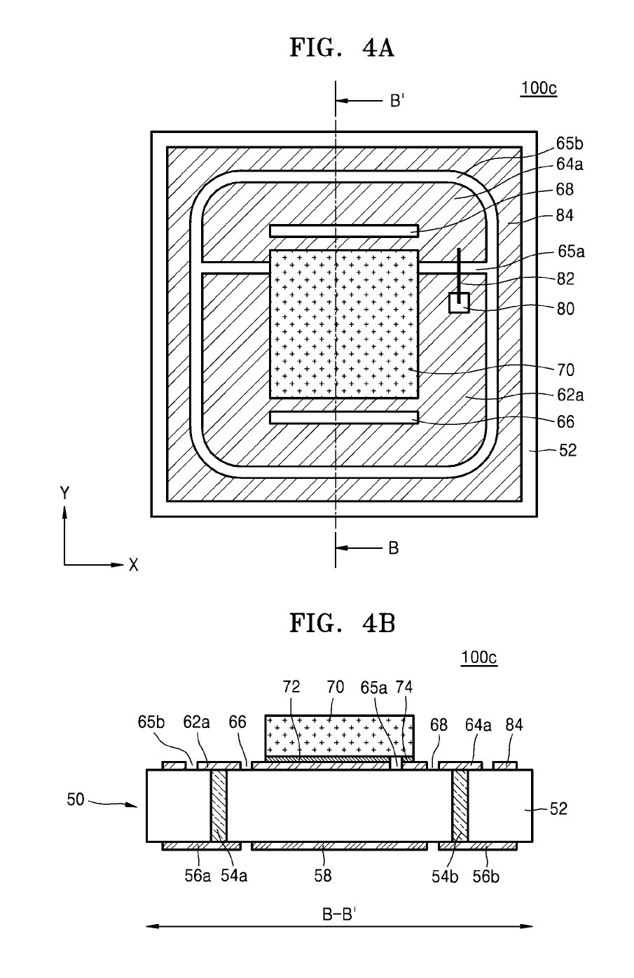

FIG. 4A is a plan view illustrating a light-emitting device package 100c according to an exemplary embodiment of the inventive concept. FIG. 4B is a cross-sectional view of the light-emitting device package 100c taken along line B-B′ of FIG. 4A. The light-emitting device package 100c is similar to the light-emitting device package 100 described with reference to FIGS. 1A and 1B except that a package substrate 50 further includes a guide layer 84.

Referring to FIGS. 4A and 4B, the package substrate 50 may include a substrate 52, a first conductive layer 62a, a second conductive layer 64a, and the guide layer 84.

The first and second conductive layers 62a and 64a may be formed at a predetermined distance from each other, and a region between the first and second conductive layers 62a and 64a is defined as a first electrode separating region 65a. The first electrode separating region 65a extends in an x direction and is symmetrical in a y direction.

The guide layer 84 may be formed on an edge of an upper surface of the package substrate 50 to enclose the first and second conductive layers 62a and 64a. In other words, the guide layer 84 is disposed at a predetermined distance from outer sides of the first and second conductive layers 62a and 64a and has an annular shape. A space between the guide layer 84 and the first conductive layer 62a and a space between the guide layer 84 and the second conductive layer 64a are defined as a second electrode separating region 65b. The first and second electrode separating regions 65a and 65b may be communicated with each other.

In FIG. 4A, edges of the first and second conductive layers 62a and 64a disposed beside both sides of the first electrode separating region 65a are formed in linear shapes. Also, edges of the first and second conductive layers 62a and 64a adjacent to a peripheral part of the substrate 52 are formed in square shapes, corners of which are rounded. Therefore, the second electrode separating region 65b is also formed in a square shape with rounded corners.

In exemplary embodiments, the first and second conductive layers 62a and 64a and the guide layer 84 may include the same materials. For example, in a process of forming the first and second conductive layers 62a and 64a and the guide layer 84, a conductive layer (not shown) is formed on the substrate 52 and then patterned to form the first and second conductive layers 62a and 64a and the guide layer 84 on the substrate 52 so that the first and second conductive layers 62a and 64a and the guide layer 84 are spaced apart from one another. In this case, the first and second conductive layers 62a and 64 and the guide layer 84 may have equal heights. Also, distances between the first and second conductive layers 62a and 64a and the guide layer 84, i.e., a width of the first electrode separating region 65a and a width of the second electrode separating region 65b, may be equal to or different from each other.

A light-emitting device 70 may be mounted on the package substrate 50 to overlap with the first and second conductive layers 62a and 64a. First and second slits 66 and 68 are respectively formed in the first and second conductive layers 62a and 64a to be parallel with a side of the light-emitting device 70. The first conductive layer 62a is electrically connected to an n electrode (not shown) of the light-emitting device 70, and the second conductive layer 64a may be electrically connected to a p electrode of the light-emitting device 70. The guide layer 84 may be spaced apart from the first and second conductive layers 62a and 64a, and thus, may not be electrically connected to the light-emitting device 70.

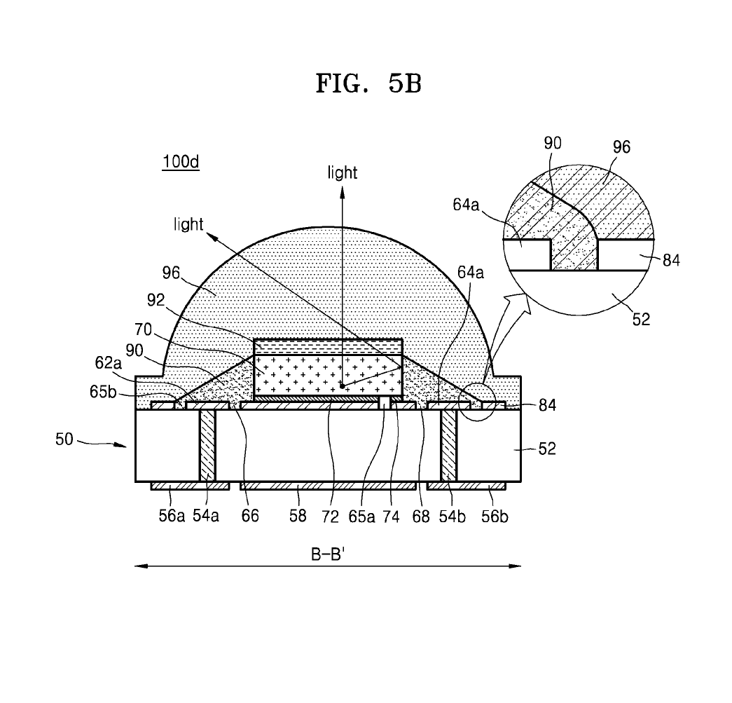

The guide layer 84 may guide a fluorescent layer (not shown) covering an upper surface of the light-emitting device 70 to be formed or may guide a reflective layer (not shown) to be formed in a predetermined shape on a sidewall of the light-emitting device 70. The guide layer 84 will be described in detail later with reference to FIGS. 5A through 6.

According to the inventive concept, each of the first conductive layer 62a, the second conductive layer 64a, and the guide layer 84 may be symmetrical in the y direction. Therefore, a stress applied to the light-emitting device 70 due to thermal expansions of the first and second conductive layers 62a and 64 may be uniformly dispersed. The first slit 66, the second slit 68, the first electrode separating region 65a, and the second electrode separating region 65b may operate as stress releasing parts that offset volume changes caused by the thermal expansions of the first and second conductive layers 62a and 64b and the guide layer 84.

FIG. 5A is a plan view illustrating a semiconductor device package 100d according to an exemplary embodiment of the inventive concept. FIG. 5B is a cross-sectional view of the light-emitting device package 100d taken along line B-B′ of FIG. 5A.

The light-emitting device package 100d of FIGS. 5A and 5B is similar to the light-emitting device package 100c described with reference to FIGS. 4A and 4B, except that the light-emitting device package 100d further includes a reflective layer 90. The light-emitting device package 100d may be a white light-emitting device package that emits white light.

A package substrate 50 may include a first conductive layer 62a, a second conductive layer 64a, and a guide layer 84 that are formed on a substrate 50. A light-emitting device 70 may be mounted on the package substrate 50 to overlap with the first and second conductive layers 62a and 64a.

The reflective layer 90 may be formed on the package substrate 50 to enclose sides of the light-emitting device 70 and covers portions of the first and second conductive layers 62a and 64a that are not covered with the light-emitting device 70. The reflective layer 90 may extend to contact at least a part of the guide layer 84. In exemplary embodiments, the reflective layer 90 may fill a space between four sides of the light-emitting device 70 and inner sidewalls of the guide layer 84 facing the light-emitting device 70. Therefore, the reflective layer 90 may be formed in an annular shape to enclose the light-emitting device 70.

In exemplary embodiments, the reflective layer 90 may be formed to contact all sides of the light-emitting device 70. Therefore, a part of the reflective layer 90 adjacent to the light-emitting device 70 may have a similar height as the light-emitting device 70, and a height of the reflective layer 90 may be lowered toward a peripheral part of the package substrate 50.

For example, the reflective layer 90 may include a material in which titanium oxide is dispersed in a silicon-based resin. In a process of forming the reflective layer 90, a reflective liquid layer compound (not shown) is injected onto the package substrate 50, and then the reflective liquid layer compound is solidified to form the reflective layer 90 so that the reflective layer 90 encloses the sides of the light-emitting device 70. Since the guide layer 84 is formed at a predetermined height to enclose an edge of the package substrate 50, a step difference occurring in the package substrate 50 due to the guide layer 84 may be used as a guide for forming an outline of the reflective layer 90. That is, the outline of the reflective layer 90 may be defined by an inner sidewall of the guide layer 84. Therefore, the reflective layer 90 may be uniformly formed to extend to an inner sidewall of the guide layer 84.

According to the inventive concept, an outline of the reflective layer 90 may be formed to contact the inner sidewall of the guide layer 84. Therefore, the outline of the reflective layer 90 may be easily controlled by modifying a pattern of the guide layer 80. For example, if the guide layer 84 is formed in a square shape, corners of which are rounded, as shown in FIG. 5A, the outline of the reflective layer 90 may be formed in a square shape, corners of which are rounded. As shown in FIG. 5A, the reflective layer 90 has a symmetrical structure in x and y directions.

In general, the light-emitting device 70 emits light through an upper surface thereof, but a portion of generated light is emitted through a lower surface and a side of the light-emitting device 70. The light emitted through the upper surface of the light-emitting device 70 may be white light, and the light emitted through the side of the light-emitting device 70 may be blue light. If the light-emitting device 70 emits light having different wavelengths through the upper surface and the side thereof, it may be difficult to reliably adjust the emitted light.

According to the inventive concept, the reflective layer 90 contacting the entire sidewalls of the light-emitting device 70 may reflect light emitted through the side of the light-emitting device 70 to emit the light through the upper surface of the light-emitting device 70 as marked with an arrow in FIG. 5B. Therefore, light may be prevented from being lost toward the side of the light-emitting device 70, and thus, the light extraction efficiency toward the upper surface of the light-emitting device 70 may be improved. Also, as blue light is prevented from being emitted toward the side of the light-emitting device 70, a wavelength of emitted light may be uniformly adjusted.

The light-emitting device package 100d may further include a fluorescent layer 92 that covers the entire upper surface of the light-emitting device 70. The fluorescent layer 92 may convert or adjust a wavelength of light emitted from the light-emitting device 70.

A lens 96 may be formed on the fluorescent layer 92 and the reflective layer 90. The lens 96 may be formed of epoxy, silicon, or the like according to a convex lens method or a transfer molding method. For example, to form the lens 96, a lens mold may be disposed on the package substrate 50, and silicon may be injected into the lens mold and then hardened. The lens 96 may form an emission pattern of emitted light.

FIG. 6 is a cross-sectional view illustrating a light-emitting device package 100e according to an exemplary embodiment of the inventive concept. The light-emitting device package 100e is similar to the light-emitting device package 100d described with reference to FIGS. 5A and 5B, except that a reflective layer is not formed.

Referring to FIG. 6, a fluorescent layer 92a may be formed to cover both an upper surface and sides of a light-emitting device 70. The fluorescent layer 92a may contact an inner sidewall of a guide layer 84. In a process of forming the fluorescent layer 92a, a compound material of the fluorescent layer 92a having liquidity may be injected into an upper surface of a package substrate 50 to cover the light-emitting device 70. Here, a step difference formed by the guide layer 84 on the package substrate 50 may be used as a guide for forming an outline of the fluorescent layer 92a. In order to control light characteristics such as a wavelength of light emitted from the light-emitting device 70, etc, it may be required that the fluorescent layer 92a covering the light-emitting device 70 is formed to a uniform thickness and in a uniform shape. According to the inventive concept, the fluorescent layer 92a may be disposed so that the outline of the fluorescent layer 92a is determined according to a pattern of the guide layer 84. Therefore, characteristics of light emitted from the light-emitting device 70 may be easily adjusted.

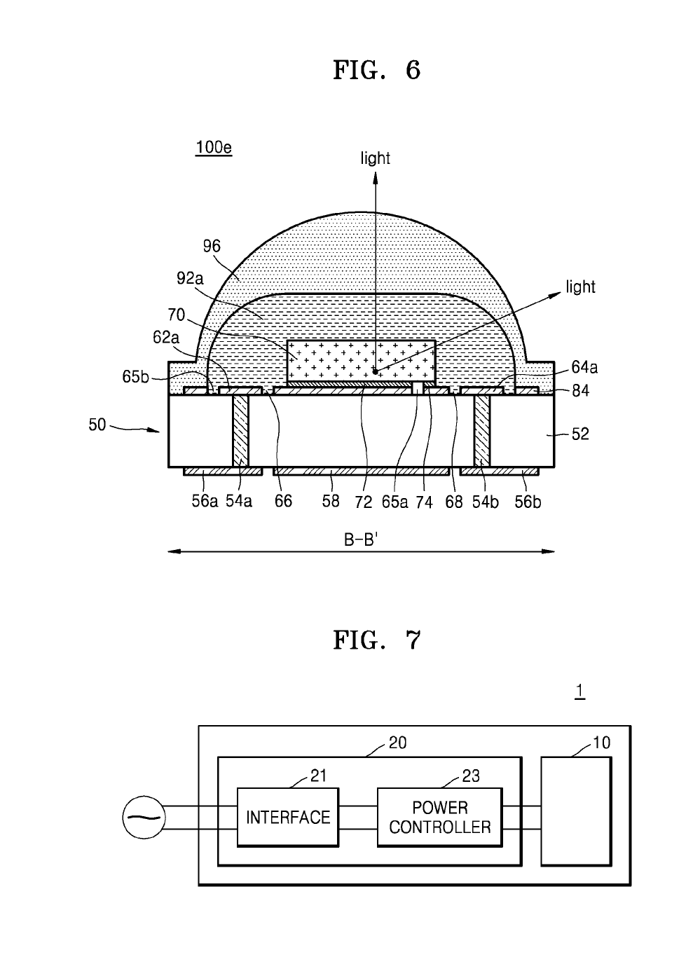

FIG. 7 is a block diagram illustrating a structure of a light-emitting device system 1 including a light-emitting device package 10 according to an exemplary embodiment of the inventive concept.

Referring to FIG. 7, the light-emitting device system 1 includes the light-emitting device package 10 and a power supply device 20 that supplies power to the light-emitting device package 10.

The light-emitting device package 10 may include one of the light-emitting device packages 100a, 100b, 100c, 100d, and 100e according to the above-described exemplary embodiments.

The power supply device 20 includes an interface 21 that receives power and a power controller 23 that controls the power supplied to the light-emitting device package 10. The interface 21 may include a fuse that interrupts an overcurrent and an electromagnetic wave shielding filter that shields an electromagnetic interference signal. The power may be supplied from an external source or an internal battery. If alternating current (AC) power is supplied, the power controller 23 may further include a rectifier that converts the AC power into direct current (DC) power and a constant voltage controller that converts the AC power into a given voltage appropriate for the light-emitting device package 10. If the power is a DC source (e.g., a battery) having a voltage appropriate for the light-emitting device package 10, the rectifier or the constant voltage controller may be omitted. Also, if a device such as an AC-LED is used as a light-emitting device of the light-emitting device package 10, the DC power may be directly supplied to the light-emitting device package 10. Even in this case, the rectifier or the constant voltage controller may be omitted.

The light-emitting device system 1 may be used as a light device in an LED tube, a flat panel light, or a lamp and may be used in a liquid crystal display system of a portable phone, a backlight unit system of a TV, a car, or the like.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A light-emitting device package comprising:
a package substrate including first and second conductive layers that are spaced apart from each other; and
a light-emitting device mounted on the package substrate to overlap with the first and second conductive layers,
wherein a portion of the first conductive layer that does not overlap with the light-emitting device has a first slit.

2. The light-emitting device package of claim 1, wherein a longitudinal direction of the first slit is substantially parallel with a side of the light-emitting device.

3. The light-emitting device package of claim 1, wherein a length of the first slit is longer than or equal to a length of a side of the light-emitting device.

4. The light-emitting device package of claim 1, wherein:
the first conductive layer comprises a first region that overlaps with the light-emitting device,
the second conductive layer comprises a second region that overlaps with the light-emitting device, and
an electrode separating region between the first and second regions extends in a direction that is substantially parallel with a side of the light-emitting device.

5. The light-emitting device package of claim 4, wherein a portion of the second conductive layer that does not overlap with the light-emitting device includes a second slit.

6. The light-emitting device package of claim 5, wherein:
an area of the first region is wider than an area of the second region, and
a width of the first slit is wider than a width of the second slit.

7. The light-emitting device package of claim 1, wherein:
a portion of the first conductive layer that overlaps with the light-emitting device has a third slit, and
the third slit is substantially parallel with the first slit.

8. The light-emitting device package of claim 1, further comprising:
a guide layer on an upper surface of the package substrate,
wherein the guide layer is disposed at a predetermined distance from outer sides of the first and second conductive layers and has an annular shape.

9. The light-emitting device package of claim 8, wherein the guide layer and the first and second conductive layers comprise the same material.

10. The light-emitting device package of claim 8, further comprising:
a reflective layer which encloses sides of the light-emitting device on the package substrate and extends to a part of an inner sidewall of the guide layer.

11. A light-emitting device package comprising:
first and second conductive layers on a substrate, the first and second layers being spaced apart from each other and adjacent to both sides of an electrode separating region that extends in a predetermined direction; and
a light-emitting device mounted on the first and second conductive layers, the light-emitting device overlapping with the electrode separating region,
wherein the first conductive layer includes a first slit extending in an extension direction of the electrode separating region, and the second conductive layer has a second slit extending in the extension direction of the electrode separating region.

12. The light-emitting device package of claim 11, wherein a side of the light-emitting device is substantially parallel with the extension direction of the electrode separating region.

13. The light-emitting device package of claim 11, wherein the light-emitting device comprises a symmetric structure in a direction perpendicular to the extension direction of the electrode separating region.

14. The light-emitting device package of claim 11, wherein:
the first conductive layer comprises a symmetric structure in a direction perpendicular to the extension direction of the electrode separating region, and
the second conductive layer has a symmetric structure in a direction perpendicular to the extension direction of the electrode separating region.

15. The light-emitting device package of claim 11, wherein:
the first slit comprises a symmetric structure in a direction perpendicular to the extension direction of the electrode separating region, and
the second slit comprises a symmetric structure in a direction perpendicular to the extension direction of the electrode separating region.

16. A light-emitting device system comprising:
a power supply device for supplying power; and
a light-emitting device package configured to receive the power from the power supply device, the package including:
a package substrate including first and second conductive layers that are spaced apart from each other; and
a light-emitting device mounted on the package substrate to overlap with the first and second conductive layers,
wherein at least one of the first and second conductive layers includes a slit provided in a portion of the first or second conductive layers that does not overlap with the light-emitting device.

17. The system of claim 16, wherein the power supply device includes:
an interface for receiving the power; and
a power controller configured to control the power supplied to the light-emitting device package.

18. The system claim 16, wherein a longitudinal direction of the slit is substantially parallel with a side of the light-emitting device.

19. The system claim 16, wherein a length of the slit is longer than or equal to a length of a side of the light-emitting device.

20. The system of claim 16, wherein:
the first conductive layer comprises a first region that overlaps with the light-emitting device,
the second conductive layer comprises a second region that overlaps with the light-emitting device, and
an electrode separating region between the first and second regions extends in a direction that is substantially parallel with a side of the light-emitting device.
